(19) United States
(12) Patent Application Publication
(10) Pub. No.: US 2015/0117110 A1
(43) Pub. Date: Apr. 30, 2015

(54) CONNECTING STORAGE GATE MEMORY

(71) Applicant: Zhijiong Luo, Hopewell Township, PA (US)

(72) Inventor: Zhijiong Luo, Hopewell Township, PA (US)

(21) Appl. No.: 14/528,915

(22) Filed: Oct. 30, 2014

Related U.S. Application Data
(60) Provisional application No. 61/898,164, filed on Oct. 31, 2013.

(51) Int. Cl. H01L 29/788; H01L 27/115; H01L 29/66; G11C 16/26

(52) U.S. Cl. CPC H01L 29/788; G11C 16/26; H01L 27/11517; H01L 29/66825
USPC 365/185.18; 257/316; 438/258

(57) ABSTRACT

Technologies are generally related to a connecting storage gate memory device, system, and method of manufacture.

### CROSS REFERENCE TO RELATED APPLICATIONS

This application claims the benefit under 35 of U.S.C. §119(e) of U.S. Provisional Patent Application Ser. No. 61/898,164 filed on Oct. 31, 2013. The disclosure of the provisional patent application is hereby incorporated by reference in its entirety.

### BACKGROUND

Increasingly, the demand from computing is for semiconductor memories to be faster and consume less energy. Presently, non-volatile memory includes floating-gate flash memory. In a floating-gate transistor, for example, the storage gate (or the charge storage layer) is floating, and may be referred to as, “a floating-gate.” The floating-gate may be used to store electrical charge. Floating-gate transistors may additionally be used as storage devices. The floating-gate transistors may be used through the floating-gate dielectric layer (or tunneling dielectric layer), which may include one or more of oxides, Fowler-Nordheim tunneling (F-N tunneling), and the hot electron injection effect. The hot electron injection effect may perform one or more from a set of: storing the floating-gate charge as electrons and removing the floating-gate charge as electrons.

The floating-gate based flash memory is a popular type of non-volatile memory, however, it possesses a slow write and a slow erase speed. The slow write and the slow erase speed of the floating-gate based flash memory prevents this type of memory from having wide applications.

### SUMMARY

This summary is provided to introduce a selection of concepts in a simplified form that are further described below in the Detailed Description. This summary is not intended to exclusively identify key features or essential features of the claimed subject matter, nor is it intended as an aid in determining the scope of the claimed subject matter.

Examples are directed to memory devices. An example memory device may include a substrate, a memory transistor and an assist transistor. The memory transistor may include a gate stack. The gate stack may include a memory gate dielectric layer positioned over the substrate, a connecting storage gate layer positioned over the memory gate dielectric layer, a control gate dielectric layer positioned over the connecting storage gate layer, and a gate electrode layer positioned over the control gate dielectric layer. The assist transistor may include a gate stack formed on the substrate and source/drain regions located on opposite sides of gate stack. One of the source/drain regions of the assist transistor may be connected to the connecting storage gate layer of the memory transistor.

Examples are directed to methods to manufacture memory devices. An example method may include forming a memory transistor on a substrate. The example method may include example steps to form a gate stack. The example method steps to form a gate stack may include, among other things, forming a memory gate dielectric layer positioned over the substrate, forming a connecting storage gate layer positioned over the memory gate dielectric layer, forming a control gate dielectric layer positioned over the connecting storage gate layer, forming a gate electrode layer positioned over the control gate dielectric layer, and forming an assist transistor comprising. The example method step to form an assist transistor may include, among other things, forming a gate stack formed on the substrate, forming source/drain regions located on opposite sides of the gate stack, and connecting the connecting storage gate layer of the memory transistor to one of the source/drain regions of the assist transistor.

These and other features and advantages will be apparent from a reading of the following detailed description and a review of the associated drawings. It is to be understood that both the foregoing general description and the following detailed description are explanatory and do not restrict aspects as claimed.

### BRIEF DESCRIPTION OF DRAWINGS

FIG. 1 illustrates a three-dimensional view of an example connecting storage gate memory device;

FIG. 2A illustrates a cross-sectional view along an AA′ direction of the connecting storage gate memory of FIG. 1;

FIG. 2B illustrates a cross-sectional view along a BB′ direction of the connecting storage gate memory of FIG. 1;

FIG. 3 illustrates a side view of an example connecting storage gate memory device with an additional contacting tunnel oxide;

FIG. 4 illustrates a side view of an example connecting storage gate memory device with a main memory transistor and an assist transistor in an active region;

FIG. 5A illustrates a substrate utilized with the process flow to manufacture the connecting storage gate memory device;

FIG. 5B illustrates a shallow trench isolation (STI) in the substrate that defines active regions on the substrate formed in the manufacture of the connecting storage gate memory device;

FIG. 5C illustrates a p-type doped region formed in the manufacture of the connecting storage gate memory device;

FIG. 5C′ illustrates a top view of the memory device after the formation of the doped region in the manufacture of the connecting storage memory gate device;

FIG. 5D illustrates a pre-patterned memory gate dielectric layer on a surface of the substrate formed in the manufacture of the connecting storage memory device;

FIG. 5E illustrates a partially patterned memory gate dielectric layer in the manufacture of the connecting storage memory gate device;

FIG. 5F illustrates a pre-patterned connecting storage gate layer on the partially patterned memory gate dielectric layer in the manufacture of the connecting storage gate memory device;

FIG. 5G illustrates the partially-patterned connecting storage gate layer on the partially patterned memory gate dielectric layer in the manufacture of the connecting storage gate memory device;

FIG. 5H illustrates the layers for gate stacks for the main memory transistor and the assist transistor in the manufacture of the connecting storage gate memory device;

FIG. 5I illustrates exposed portions of a second active region in the manufacture of the connecting storage gate memory device;

FIG. 5I′ illustrates exposed portions of a first active region and a second active region in the manufacture of the connecting storage gate memory device;

FIG. 5J illustrates heavily n-type doped regions in the first active area and a heavily p-type doped region in the second active region in the manufacture of the connecting storage memory gate device;

FIG. 5F illustrates a top view of the device in FIG. 5J after part of the stack is cut away in the manufacture of the connecting storage gate memory device;

FIG. 5K illustrates a cross-sectional view along the AA′ line in FIG. 5J′ in the manufacture of the connecting storage gate memory device;

FIG. 5K′ illustrates a cross-sectional view along the BB′ line in FIG. 5J′ in the manufacture of the connecting storage gate memory device;

FIG. 6A illustrates a trench near a shallow trench isolation (STI) in a doped region in the manufacture of a connecting storage gate memory device with an additional contacting tunnel oxide;

FIG. 6B illustrates a thin tunnel dielectric layer formed on sidewalls and a bottom of a trench in the manufacture of a connecting storage gate memory device with an additional contacting tunnel oxide;

FIG. 6C illustrates an extension of a connecting storage gate over the contacting tunnel oxide in the manufacture of a connecting storage gate memory device with an additional contacting tunnel oxide;

FIG. 6B′ illustrates a dielectric layer over a trench near a shallow trench isolation (STI) and a surface of substrate in the manufacture of a connecting storage gate memory device with an additional contacting tunnel oxide;

FIG. 6C′ illustrates an extension of a connecting storage gate over the contacting tunnel oxide in the manufacture of a connecting storage gate memory device with an additional contacting tunnel oxide;

FIG. 7A illustrates a substrate utilized for a partial fabrication process of the connecting storage gate memory device with a main memory transistor and an assist transistor in an active region;

FIG. 7B illustrates a gate stack formed for use in a partial fabrication process of the connecting storage gate memory device with a main memory transistor and an assist transistor in an active region;

FIG. 7C illustrates parts of source/region regions of a partial fabrication process of the connecting storage gate memory device with a main memory transistor and an assist transistor in an active region;

FIG. 7D illustrates a p-type doped region formed in the n-type doped region for use in a partial fabrication process of the connecting storage gate memory device with a main memory transistor and an assist transistor in an active region, according to some examples disclosed herein.

### DETAILED DESCRIPTION

As briefly described above, increasingly, the demand from computing is for semiconductor memories to be faster and consume less energy. Methods, systems, and techniques, as briefly described above, include fabricating storage gate memory devices. Examples disclosed herein provide a memory device and the manufacturing and operation methods thereof.

In the following detailed description, references are made to the accompanying drawings that form a part hereof, and in which are shown by way of illustrations specific examples or examples. These aspects may be combined, other aspects may be utilized, and structural changes may be made without departing from the spirit or scope of the present disclosure. The following detailed description is therefore not to be taken in the limiting sense, and the scope of the present disclosure is defined by the appended claims and their equivalents.

Generally, program modules include routines, programs, components, data structures, and other types of structures that perform particular tasks or implement particular abstract data types. Moreover, those skilled in the art will appreciate that examples may be practiced with other computer system configurations, including hand-held devices, multiprocessor systems, microprocessor-based or programmable consumer electronics, minicomputers, mainframe computers, and comparable computing devices. Examples may also be practiced in distributed computing environments where tasks are performed by remote processing devices that are linked through a communications network. In a distributed computing environment, program modules may be located in both local and remote memory storage devices.

Examples may be implemented as a computer-implemented process (method), a computing system, or as an article of manufacture, such as a computer program product or computer readable media. The computer program product may be a computer storage medium readable by a computer system and encoding a computer program that comprises instructions for causing a computer or computing system to perform example process(es). The computer-readable storage medium can for example be implemented via one or more of a volatile computer memory, a non-volatile memory, a hard drive, a flash drive, a floppy disk, or a compact disk, and comparable media.

In the following detailed description, reference is made to the accompanying drawings, which form a part hereof. In the drawings, similar symbols typically identify similar components, unless context dictates otherwise. The illustrative examples described in the detailed description, drawings, and claims are not meant to be limiting. Other examples may be utilized, and other changes may be made, without departing from the spirit or scope of the subject matter presented herein. The aspects of the present disclosure, as generally described herein, and illustrated in the Figures, can be arranged, substituted, combined, separated, and designed in a wide variety of different configurations, all of which are explicitly contemplated herein.

In the following detailed description, when one layer/element is described as on another layer/element. The above layer/component/element can be located directly on the other layer/component, or middle layers/elements can exist between them.

This disclosure is generally drawn to connecting storage gate memory devices, as well as systems, methods, and techniques to fabricate and use such devices.

Briefly stated, technologies are generally described to a connecting storage gate memory device, system, and method of manufacture.

Various described devices include utilization of a connecting storage gate for a memory device to increase the write and erase speed and to increase storage capacity. The connecting storage memory transistors may include a main storage memory transistor unit which may include a gate stack. The gate stack may be formed on a substrate. The gate stack may include a memory gate dielectric, a connecting storage gate, a control gate dielectric, and a gate electrode. The connecting storage gate may be configured to store electrical charges, which may store data in a memory device. The connecting storage memory device may also include an assist transistor unit. The assist transistor unit may be connected to the main storage transistor unit. The assist transistor unit may store charges to the connecting storage gate. The assist transistor unit may remove charges from the connecting storage gate. The connecting storage memory device may use one or more from a set of: store the charge in the connecting storage gate electrode and remove the charge in the connecting storage gate electrode.

The assist transistor unit may include the gate stack on a substrate and the source/drain regions on opposite sides of gate stack. The connecting storage gate may connect to one from a set of: the source region of the assist transistor and the drain region of the assist transistor. The connecting storage gate in the connecting storage gate memory device may be connected to one of the source/drain regions of the assist transistor. In some examples, the connecting storage gate may not be floating. The assist transistor unit may be normally in a form similar to a metal-oxide-semiconductor (MOS) transistor. Using the assist transistor may enhance charge storage speed and removal speed on the connecting storage gate, which may improve a write speed and an erasure speed of the memory device.

The electrical connection between the main memory transistor and assist transistor may be achieved through one from a set of: physical contact and extension of each other. For example, the connecting storage gate may extend and may make contact to one of the source/drain regions of the assist transistor, which may make physical and electrical contact. In some examples, the contact region may be a source side of the assist transistor. In addition, the gate electrode of the main memory transistor and the gate electrode of the assist transistor may be integrated continuously with each other (i.e. formed by the one continuous layer of material) which may also electrically connected to each other. Furthermore, the control gate dielectric layer of the main memory transistor and the gate dielectric of the assist transistor assist transistor may also be integrated continuously with each other.

The main memory transistor unit and the assist transistor unit may be formed on adjacent different active regions on a substrate. The active region may be separated by shallow trench isolation (STI). In this case, in the first active region, the channel of the main memory transistors may extend along a first direction, while in the second active region, the channel of the assist transistor may be along a second direction, which is crossed with the first direction. In some examples, the second direction is substantially perpendicular to the first direction, where this configuration may facilitate the main memory transistor unit and the assist transistor unit into one.

In another example, the main memory transistor unit and the assist transistor unit may also be formed in the same active region in a substrate. For example, the active region may be the first doping type, and a relative lightly-doped well area of the second doping type may located in the active region. The first doping type and second doping type are of opposite polarity. The well area with the second doping type serves as one of the source/drain regions for the main memory transistors. The assist transistor unit is formed in the well area with the second doping type.

In the following, the memory state with charges stored on the connecting storage gate is represented by bit 1. The memory state with essentially no stored charge on the connecting storage gate is represented by bit 0. It should be noted that at the bit 1 and bit 0 definition are interchangeable. In the connecting storage memory device operation, in the write and erase stage, the assist transistor unit is at the open state. In the storage stage, the assist transistor unit and the main memory unit are at the close state. In the read storage, the assist transistor unit is at the close state and the main memory transistor unit is at the open state.

For example, to write bit 1 into the memory device, the assist transistor is at the open state, and the channel of the assist transistor is open. By applying a voltage bias within predefined limits, the charges flow through the channel of the assist transistor. The connecting storage gate may be connected to one from a set of: the source of the assist transistor and the drain region of the assist transistor. In this example, the connecting storage gate is connected to the source of the assist transistor. The charges flow from the source of the assist transistor into the connecting storage gate and may be stored there.

To write bit 0 into the memory device indicates removal of charges (i.e. an erasure). For example, to write bit 0 into the memory device, the assist transistor is at the open state by an application of a different voltage bias to the source. Also, this allows for a drainage of the assist transistor to allow the charges to flow out from the connecting storage gate and into the source of the assist transistor. The source/drain of the assist transistor are interchangeable. In the write operation, the main memory transistor may be at a closed state and a different voltage bias may be applied to the connection storage gate memory device to ensure the correct operation to write one from a set of: a bit 1 and a bit 0 into the memory device.

In the read operation, the assist transistor may be at the closed state and the main memory transistor may be at the open state. Depending on if the assist transistor is at the closed state and/or if the main memory transistor is at the open state, charges may be stored at the connecting storage gate. The amount of the charges stored at the connecting storage gate may affect the threshold voltage of the main memory transistor. The threshold voltage shift may cause read current change. The read current change may be detected by checking the current flow through the main memory transistor under voltages. The data stored on the memory device may be read out. If the assist transistor is kept at the close state during the read operation, this may prevent the stored charge leaked out.

In examples, in the write operation and in the read operation, the main memory transistor and the assist transistor are in the opposite state at the same time period. For example, when the main memory transistor is in the open state, the assist transistor is in the closed state during a first time period. For example, when the main memory transistor is in the closed state, the assist transistor is in the open state during a second time period.

Implemented in an example, the main memory transistor and the assist transistor may have opposite semiconductor device types. For example, if the main memory transistor is an n-type device, then the main memory transistor's accompanying assist transistor is a p-type device.

In an additional example, if the main memory transistor is the p-type device, the main memory transistor's accompanying assist transistor is the n-type device. In this example, when a voltage is applied to the gate electrode of the main memory transistor and the gate electrode of the assist transistor, due to the opposite device types, under the certain same control signal, when one of the main memory transistor and the assist transistor is at the open state, the other one of the main memory transistor and the assist transistor is at the closed state. The control gate of main memory transistor gate and the gate of the assist transistor gate may be physically and electrically connected. In addition, the main memory transistor and the assist transistor unit may be formed on a substrate by one or more semiconductor transistor manufacturing processes.

The connecting storage gate may be extended to contact the one or more of a source region and a drain region of the assist transistor; by doing so, the connecting storage gate may be electrically connected to the assist transistor. In addition, the control gate electrode of the main memory transistor and the gate electrode of the assist transistor may be formed by a continuous conducting layer of material and may be integrated continuously. Furthermore, a control oxide layer of the main memory transistor and the gate dielectric layer of the assist transistor may also be formed by a continuous layer of material and may be integrated continuously with each other.

The gate stack of the main memory transistor unit and the assist transistor unit may be integrated together continuously. For example, in a first active region, a memory gate dielectric layer of the main memory transistor may be formed. The connecting storage gate layer may be formed on top of the memory gate dielectric layer, which may lie on the first active region and may extend to one of the source/drain regions of the assist transistor.

One layer of dielectric may be formed on top of the connecting storage gate layer, which may be located on both the first and second active regions. On the first active region, the dielectric layer may be used as a control oxide layer for the main memory transistor. In the second active region, the dielectric layer may be used as the gate dielectric layer of the assist transistor. A gate electrode layer may be formed on the dielectric layer, which may be located on both the first and second active regions. On the first active region, the gate electrode layer may be used as the gate electrode layer for the main memory transistor. In the second active region, the gate electrode layer may be used as the gate electrode of the assist transistor.

In some examples, the first active region and second active region may be formed in a substrate. The main memory transistor and the first transistor may be formed on the two active regions, respectively. For example, the source region of the assist transistor may be formed first. The source region may be used to connect the connecting storage gate. The gate stack for the main memory transistor may then be fabricated on the first active region. The gate stack for the assist transistor may be formed simultaneously. Next, using the gate stack as a mask, the source/drain regions for the main memory transistor may be formed in the first active region. Lastly, the drain area of the assist transistor may be formed in the second active region.

In another example, the main memory transistor unit and the assist transistor unit may be formed adjacent in the same active region. In one example, the two transistors may have opposite polarities. For example, if the source/drain areas of the assist transistor include a first doping type, the main memory transistor is the second device type, and its source/drain areas are the second doping type, the source or drain area of the main memory transistor may be expanded into a well region, and the assist transistor may be formed in the well region. The two units may be formed in the same active region.

The disclosed memory devices may be presented in various forms, some examples of which will be described below.

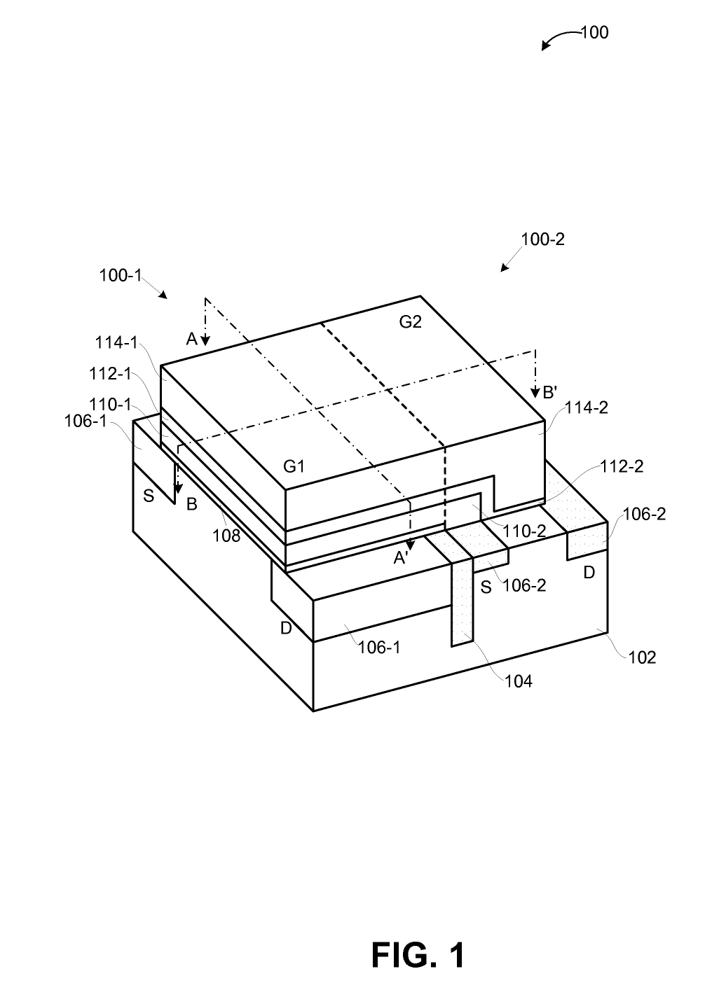

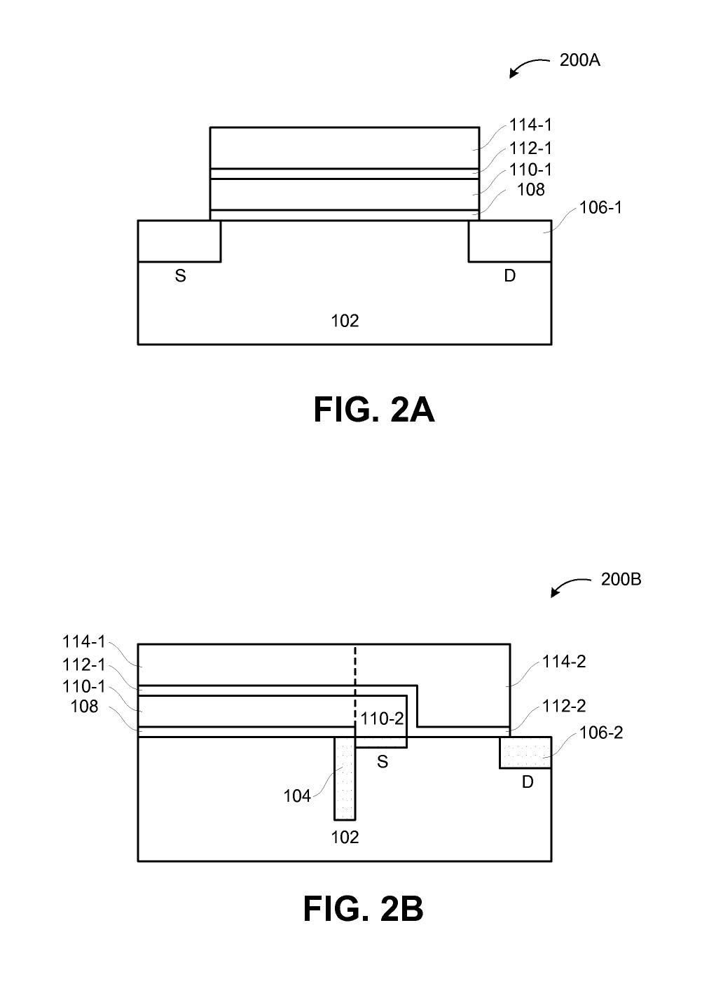

FIG. 1 illustrates a three-dimensional view of an example connecting storage gate memory device, according to at least some examples disclosed herein. FIG. 2A illustrates a cross-sectional view along an AA′ direction of the connecting storage gate memory of FIG. 1, according to at least some examples disclosed herein. FIG. 2B illustrates a cross-sectional view along a BB′ direction of the connecting storage gate memory of FIG. 1, according to at least some examples disclosed herein.

As shown in FIGS. 1, 2A, and 2B, the storage memory device 100, 200A, 200B, respectively, may include a substrate 102. The substrate 102 may be a suitable substrate in various forms, such as a bulk semiconductor substrate. The semiconductor substrate may include one or more from a set of: silicon (Si), germanium (Ge), a bulk silicon substrate, a semiconductor substrate, and a semiconductor on an insulator (SOI), among others. Examples of the compound semiconductor substrates include, among others, silicon-germanium (SiGe), gallium arsenide (GaAs), gallium antimonide (GaSb), aluminum arsenide (AlAs), indium monoarsenide (InAs), indium phosphide (InP), gallium nitride (GaN), silicon carbide (SiC), indium gallium arsenide (InGaAs), indium antimonide (InSb), and indium gallium antimonide (InGaSb). It should be noted that the present disclosure is not limited thereto. In this example, the substrate 102 may be lightly p-type doped.

In the substrate 102, a shallow trench isolation (STI) 104 may be formed. As shown in the FIG. 1, a first direction extending along the STI 104, so as to cross a second direction, the first direction and the second direction are substantially perpendicular. Here, for convenience, the active region on the left side of STI may be referred to as “the first active region”, while the active region on the right side of STI referred to as “the second active region.” It should be noted that the present disclosure is not limited to the diagrammed STI; there may be other STI existing to surround an active region. The other STI and the STI 104 may enclose certain active areas, so that the first active region and the second active region are limited to a certain areas.

In the first active region, the memory transistor may be formed. The memory transistor may include a gate stack G1, and the source/drain regions 106-1 located on opposite sides of the gate stack G1.

The gate stack G1 may include a memory gate dielectric layer 108, the connecting storage gate layer 110-1, a control gate dielectric layer 112-1, and the control gate electrode 114-1. The memory gate dielectric layer 108 may be one or more from a set of: oxides (e.g., silicon oxide), nitrides (e.g., silicon nitride), nitride oxides (e.g., silicon oxynitride), metal oxides, and a combination of the above. The memory gate dielectric layer 108 may have a thickness of about 5 to about 200 Å. The connecting storage gate layer 110-1 may be one or more from a set of: polysilicon, amorphous silicon, germanium, silicon germanium, a compound semiconductor, metal, and the combination of the above. The connecting storage gate layer 110-1 may have a thickness of about 10 to about 10000 Å.

The connecting storage gate 110-1 may store electric charge. The control gate dielectric 112-1 may be one or more from a set of: oxides (e.g., silicon oxide), nitrides (e.g., silicon nitride), nitride oxides (e.g., silicon oxynitride), metal oxides, and a combination of the above. The control gate dielectric may have a thickness of about 5 to about 5000 Å. The control gate electrode 114-1 may include one or more from a set of: doped polycrystalline silicon, un-doped polycrystalline silicon, doped amorphous silicon, un-doped amorphous silicon, doped germanium, un-doped germanium, doped silicon germanium, un-doped silicon germanium, a doped compound semiconductor, an un-doped compound semiconductor, a doped metal, an un-doped metal, and a combination of the above. The control gate electrode 114-1 may have a thickness of about 10 to about 10000 Å.

By applying the control signal on the control gate electrode 114-1, the channel of the main memory transistor may be turned from an open state to a closed state, or vice versa. The above materials may be formed by one or more from a set of: thermal growth, chemical vapor deposition (CVD), physical vapor deposition (PVD), atomic layer deposition (ALD), molecular beam epitaxy (MBE), and etc.

The source/drain regions 106-1 include a source region S and a drain region D. The source region S and the drain region D may be located on opposite sides of the gate stack G1. The source/drain regions 106-1 may be doped regions formed in the substrate 102. For example, the source/drain regions 106-1 may be n-type doped, so that the main memory transistor may be the n-type device. In this example, the control gate electrode 114-1 may be n-type doped. The channel may be formed between the source region S and the drain region D. The channel of the main memory transistor may extend substantially along the first direction and may be controlled by the gate stack G1 (specifically, the control gate electrodes 114-1).

In this example, the source region 106-1 is labeled as the source region S and the other source/drain region of 106-1 is labeled as the drain region D. The source region S and the drain region D are substantially the same in structure. As such, the source region S and the drain region D may be interchanged.

Further, the source/drain regions 106-1 may have a rectangular cross-section; this is only illustrative. For example, a source/drain region 106-1 in the substrate 102 may be formed by ion implantation. In this case, the shape of the source/drain regions 106-1 may be defined by the ion implantation and diffusion. In a second active region, the assist transistor may formed. The assist transistor may include a gate stack G2 and the source/drain regions 106-2 located on opposite sides of the gate stack G2.

The gate stack G2 may include a gate dielectric 112-2 and a gate electrode 114-2. The gate dielectric 112-2 may include one or more from a set of: oxides (e.g., silicon oxide), nitrides (e.g., silicon nitride), nitride oxides (e.g., silicon oxynitride), metal oxides, and a combination of the above. The gate dielectric 112-2 may have a thickness of about 5 to about 5000 Å. The gate electrode 114-2 may include one or more from a set of: doped polycrystalline silicon, un-doped polycrystalline silicon, doped amorphous silicon, un-doped amorphous silicon, doped germanium, un-doped germanium, doped silicon germanium, un-doped silicon germanium, a doped compound semiconductor, an un-doped compound semiconductor, a doped metal, an un-doped metal, and a combination of the above. The gate electrode 114-2 may have a thickness of about 10 to about 10000 Å. By applying the control signal on the gate electrode 114-2, the channel of the assist transistor may be controlled to one or more from a set of: the open position and the closed position.

The source/drain regions 106-2 may include the source region S and the drain region D on opposite sides of the gate stack G2 along the second direction. The source/drain regions 106-2 may be doped. Additionally, the source/drain regions 106-2 may be formed in the substrate 102. For example, the source/drain regions 106-2 may be p-type doped, so that the assist transistor may be a p-type device. In this case, the second active region may be an n-well (not shown), and the source/drain regions 106-2 may be formed in the n-well. Further, the gate electrode 114-2 may be p-type doped. The channel region may be between the source region S and the drain region D. The channel region may extend substantially along the second direction and may be controlled by the gate stack G2 (specifically, the gate electrode 114-2). Similarly, the source region S and drain region D may be substantially the same in structure, and may be used interchangeably.

In some examples, the main memory transistor and the assist transistor may extend in different directions. As such, the main memory transistor and the assist transistor may be set in an arrangement where one from the set of: the source region of the assist transistor is set adjacent to the main memory transistor and the drain region of the assist transistor is set adjacent to the main memory transistor. Specifically, the source region S may extend substantially along the direction of the main memory transistor channel. The connecting storage gate of the main memory transistor may be extended and may be connected to the source region S of the accompanying assist transistor in this example. In addition, this configuration may also facilitate the main memory transistor gate stack G1. In this configuration, the assist transistor gate stack G2 may be integrally formed, as described below, which may facilitate the realization of the electrical connection between the two.

Specifically, the connecting storage gate of the main memory transistor 110-1 may extend (over STI 104) to the source region S of the assist transistor. The extension portion may be referred to as “110-2.” The extension portion 110-2 and the source region S of the assist transistor may be in physical contact and electrically connected to each other. The extension portion 110-2 may be doped with the same doping type as the source region (e.g., p-type doping, in this example).

Further, the control gate electrode of the main memory transistor 114-1 and the gate electrode of the assist transistor 114-2 can be integrated continuously into one part. The control gate electrode 114-1 and the gate electrode 114-2 can be doped with different polarities, and also can be doped with the same polarity. Moreover, the control gate oxide of the memory transistor 112-1 and the gate oxide of the assist transistor 112-2 can be integrated into one part as well. In this example, the channel of the main memory transistor and the channel of the assist transistor are arranged along the first direction and second direction, respectively. The first direction and the second direction are crossed substantially perpendicular to each other. Therefore, the connecting storage gate layer, the control gate dielectric layer, and the control gate electrode of the main memory transistor may be extended to the second active region. Thus, in this example, in fact, the gate stack G1 and the gate stack G2 may be viewed as one single integrated gate stack. In this case, the boundaries of the gate stack G1 and the gate stack G2 may be schematically shown in dashed lines in the Figures. This border is only to divide the gate stack G1 and the gate stack G2 functionally: one for the main memory transistor, and the other for the assist transistor; but in this example, they are not physically divided. The gate stack G1 and the gate stack G2 may be in separated formation as well.

Further, the connecting storage gate memory device may also include a contact portion to the gate electrodes 114-1 and 114-2, a contact portion to the source region of the main memory transistor, a contact portion to the drain region of the main memory transistor, and a contact portion to the drain region of the assist transistor.

In FIGS. 1, 2A, and 2B, the edges of the memory gate dielectric 108 may be shown as aligned with the edge of the STI 102. The edge of the extension portion 110-2 may be shown aligned with the edge of the drain region D of the assist transistor. This is shown for convenience of illustration. As it may occur to persons skilled in the art, any suitable positional relationship, as long as each of the main memory transistor's and the assist transistor's gate stack and source/drain regions as can be fitted to each other, transistors may operate effectively.

In some examples, when writing bit 1 into the memory device, the control gate electrode 114-1 and the gate electrode 114-2 and the drain region D of the assist transistor may be negatively biased. Since the control gate electrode 114-1 and the gate electrode 114-2 are negatively biased, the n-type main memory transistor is in the closed position and the p-type assist transistor is in the open position and conducting. In this example, the drain region D of the assist transistor is negatively biased and the charges may go into the extension portion 110-2, the connecting storage gate 110-1, and may be stored in the connecting storage gate 110-1.

In some examples, when writing bit 0 into the memory device, the control gate electrode 114-1 and the gate electrode 114-2 may be negatively biased and the drain region D of the assist transistor may be positively biased. Since the control gate electrode 114-1 and the gate electrode 114-2 is negatively biased, the n-type main memory transistor may be in the closed position, and the p-type assist transistor is in the open position and conducting. In this example, the drain region D of the assist transistor is positively biased, so the charges stored in the connecting storage gate 110-1 and in the extension portion 110-2 may be removed by the assist transistor. The charges may flow out and the stored charges may be erased.

In another example, the control gate electrode 114-1 and the gate electrode 114-2 may be determined to be positively biased through reading the data stored in the connecting storage memory device 100. In this example, the n-type main memory transistor is in the open position, and the p-type assist transistor is in the closed position. The charges stored in the connecting storage gate 110-1 may cause the shift of the threshold voltage and the threshold voltage shift may lead to changes in the read current. The change of current may be detected and the data stored in the connecting storage gate memory device 100 may be read out. In read operation, the assist transistor may be closed to prevent the charges stored on the connecting storage gate 110-1 to leak out.

In the example, as storing charge and erasing charge storage on the charge storage gate is mainly carried out by the assist transistor, the write speed and the erase speed of the memory is improved. However, since the connecting storage gates are not completely electrically isolated, there may be a reduction in the data retention time. Use of the SOI substrate may improve the data retention time of the connecting storage gate memory device. Further, the connecting storage gate 110-1 and the extension portion 110-2 may have a larger capacity to store the charges than the normal floating gate in a flash memory device with the similar dimension. As such, the connecting storage gate memory may have the potential to store more charges. Also, the memory gate dielectric 108 may be thicker than normal tunnel gate dielectric in a flash memory device, which may help to increase the retention time as well.

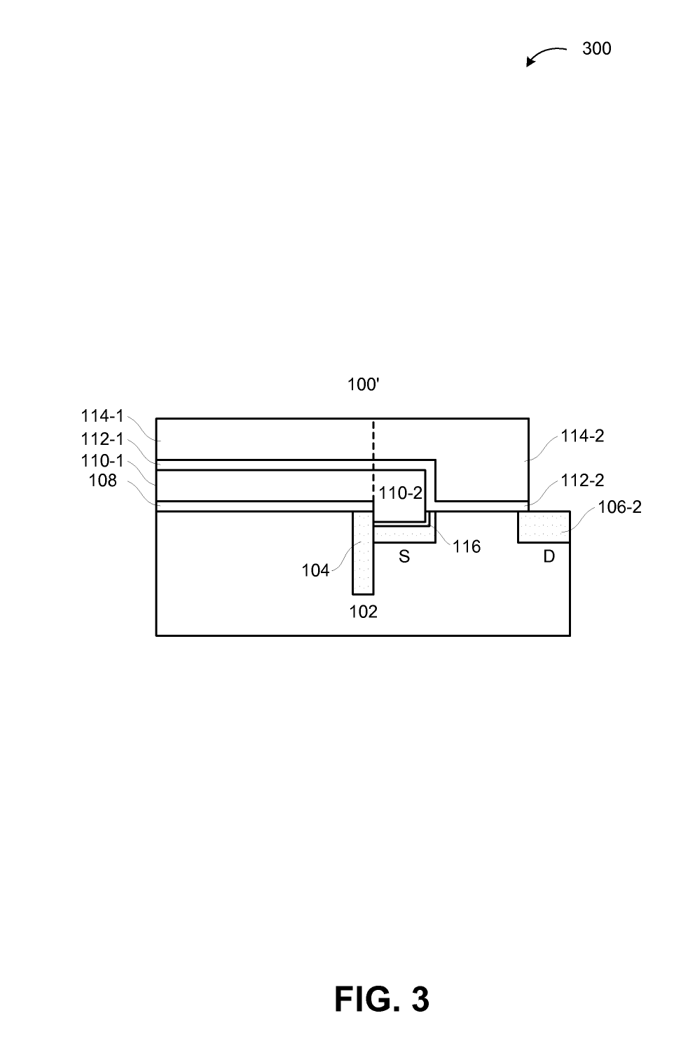

FIG. 3 illustrates a side view of an example connecting storage gate memory device with an additional contacting tunnel oxide, according to at least some examples disclosed herein.

The source region S of the assist transistor, in FIG. 3, is electrically connected to the connecting storage gate 110-1 and the extension portion 110-2 via a contact tunneling dielectric layer 116. The contact tunneling dielectric layer 116 may include one or more from the set of: oxides (e.g., silicon oxide), nitrides (e.g., silicon nitride), nitride oxides (e.g., silicon oxynitride), metal oxides, and the combinations of the above. The contact tunneling dielectric layer 116 may have a thickness of about 2 Å to about 100 Å. The assist transistor may perform one or more from a set of: move charges into the connecting storage gate by the tunneling currents through the contact tunnel dielectric layer 116 and out the connecting storage gate by the tunneling currents through the contact tunnel dielectric layer 116. The contact tunneling dielectric layer 116 may improve data retention time.

The operation of the memory device 100′ is similar to the operation of the memory 100 in FIGS. 1, 2A, and 2B. In the above examples, the main memory transistor and the assist transistor may be formed in different active regions. However, the present disclosure is not limited thereto, and for example, the main memory transistor and the assist transistor may be formed in the same active region.

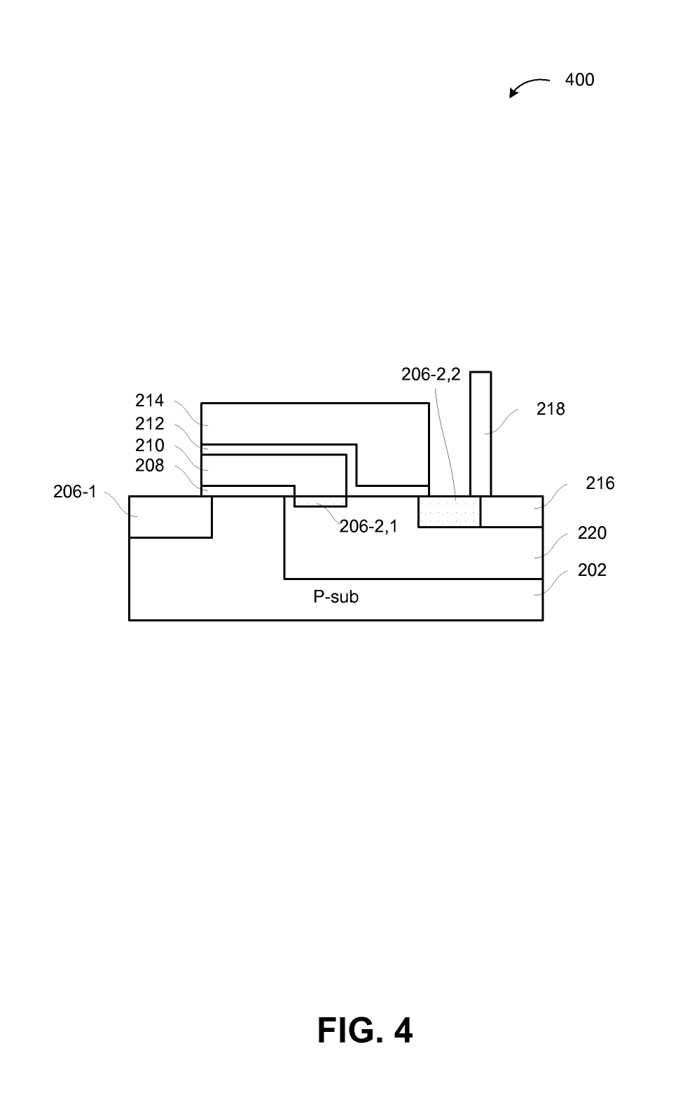

FIG. 4 illustrates a side view of an example connecting storage gate memory device with a main memory transistor and an assist transistor in an active region, according to at least some examples disclosed herein.

According to FIG. 4, a diagram 400 may include a connecting storage gate memory device. The connecting storage gate memory device may include a substrate 202. The substrate 202 may be ion implanted, for example, be p-type doped. Here, the bulk silicon substrate may be used as an example. However, as described above, the present disclosure is not limited thereto.

A shallow trench isolation (STI) may be formed in the substrate 202 to define an active region. FIG. 4 shows the active region. The active region may be lightly p-doped. In the active region, for example, ion implantation may be used to form a light n-type well region 220. Additionally, the assist transistor may be formed in the n-type well region 220.

One of the source/drain regions of the main memory transistor 206-1 may be located outside of the n-type well region 220, but located inside of the p-type active area. The n-type well region 220 may act as another source/drain region of the main memory transistor. In the main memory transistor, for example, is the source region 206-1, and a current may flow between the source region 206-1 and the n-type well region 220. In this example, the source region 206-1 may be n-doped. Therefore, the main memory transistor is an n-type device.

The main memory transistor also includes a gate stack, in some examples. The gate stack may include a sequentially stacked a memory gate dielectric 208, a connecting storage gate 210, a control gate dielectric 212 and a control gate electrode 214. The assist transistor may include the source region 206-2,1 and the drain region 206-2,2, which may be within the n-type well region. In this example, the source region 206-2,1 and the drain region 206-2,2 may be p-doped. Therefore, the assist transistor is p-type device.

The assist transistor may also include a gate stack. The gate stack may comprise the sequentially stacked gate dielectric 212 and the gate electrode 214. In this example, the gate stack of the main memory transistor and the gate stack of the assist transistor may be integrated continuously. For the gate stack configuration, you can refer to the above description, and are not discussed in details at here.

Also, the memory device may further include a contact region 216 in the n-type well region. The contacting region 216 may be heavily n-doped, to allow for a contact to be made to the n-type well region 220 through the contact region 216.

In this example, the contact region 216 and the drain region 206-2,2 of the assist transistor may be located immediately adjacent to each other. The contact region 216 and the drain region 206-2,2 may share the same contact 218. However, the present disclosure is not limited thereto. For example, the contact region 216 and the drain region 206-2,2 of the assist transistor may be separated from each other and may each have a respective contact portion. In this example, the source region of the assist transistor 206-2,1 may also be connected to the connecting storage gate of the main memory transistor 210 via a thin contact tunneling dielectric layer.

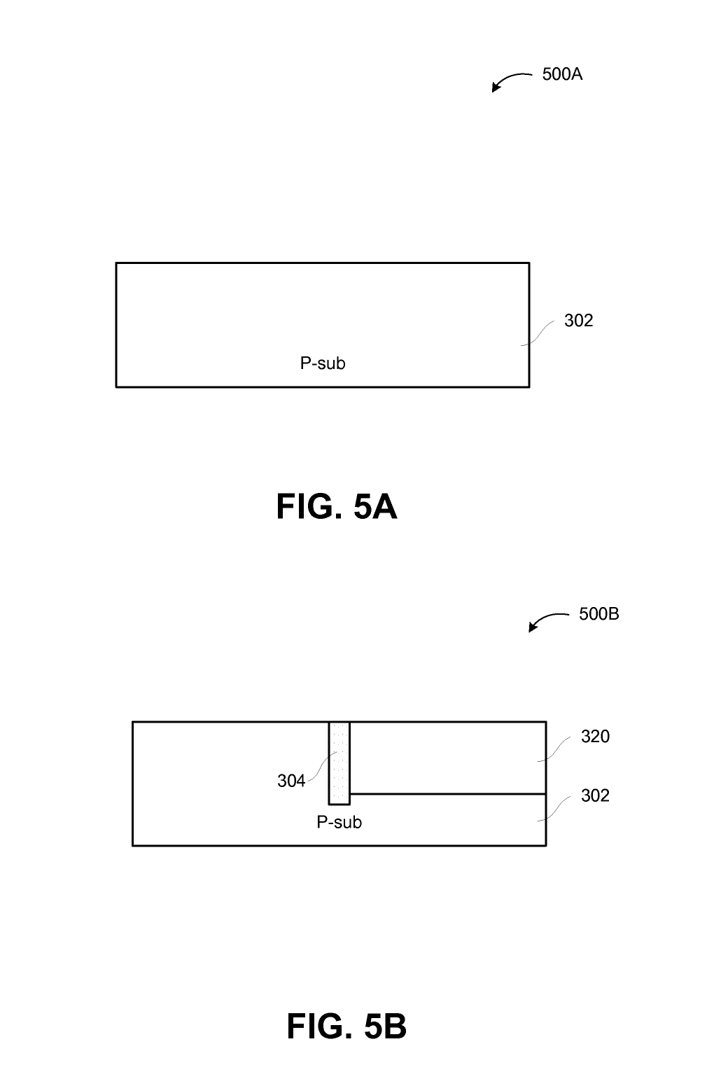

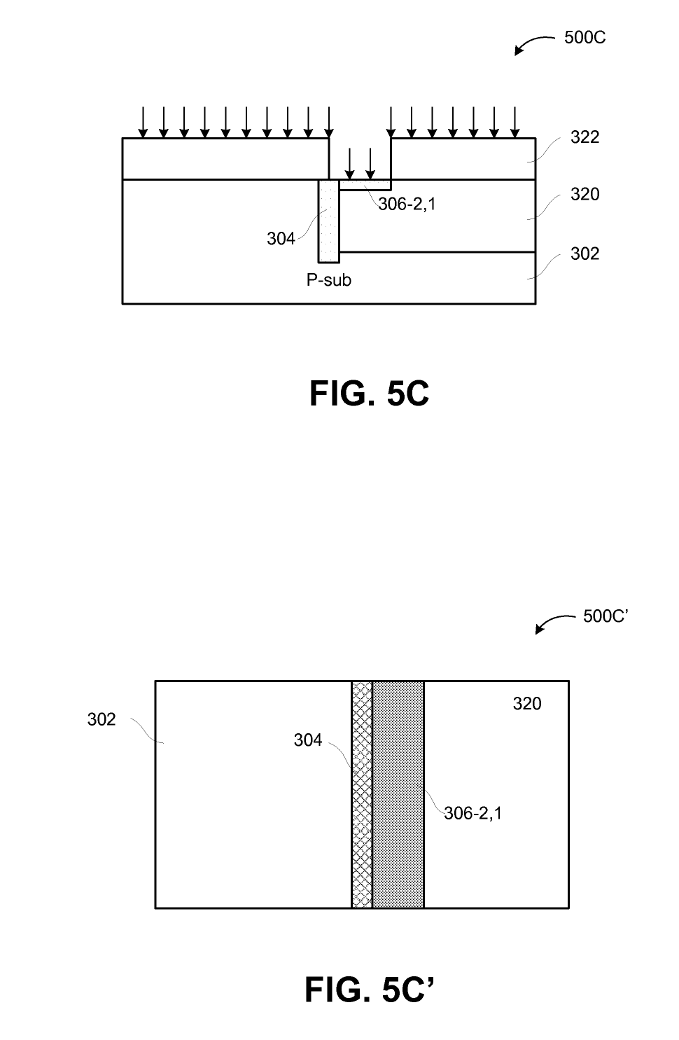

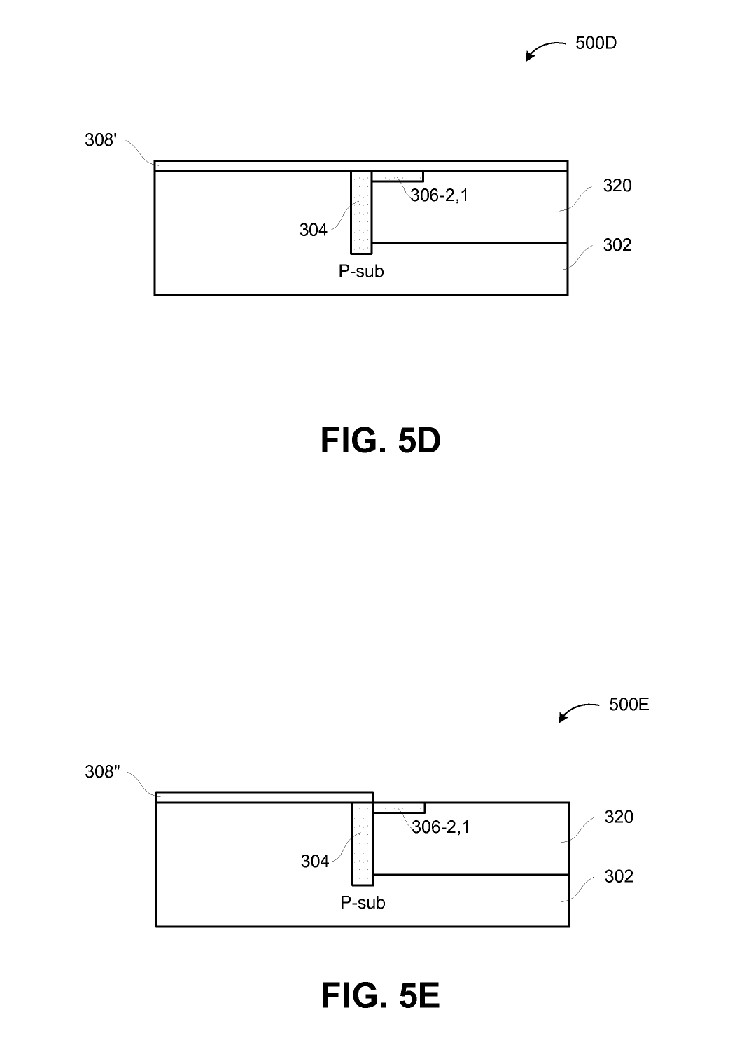

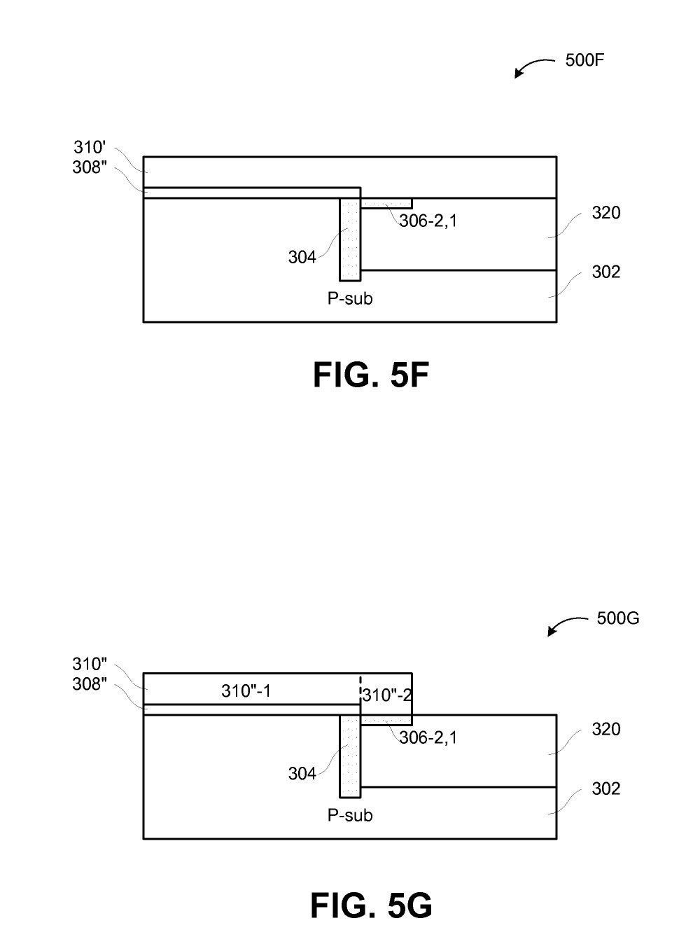

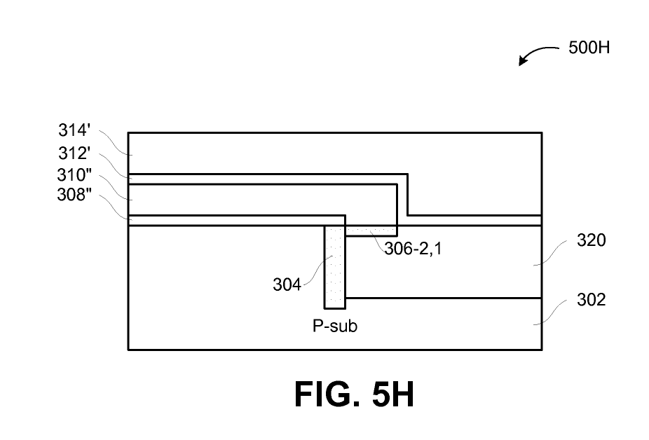

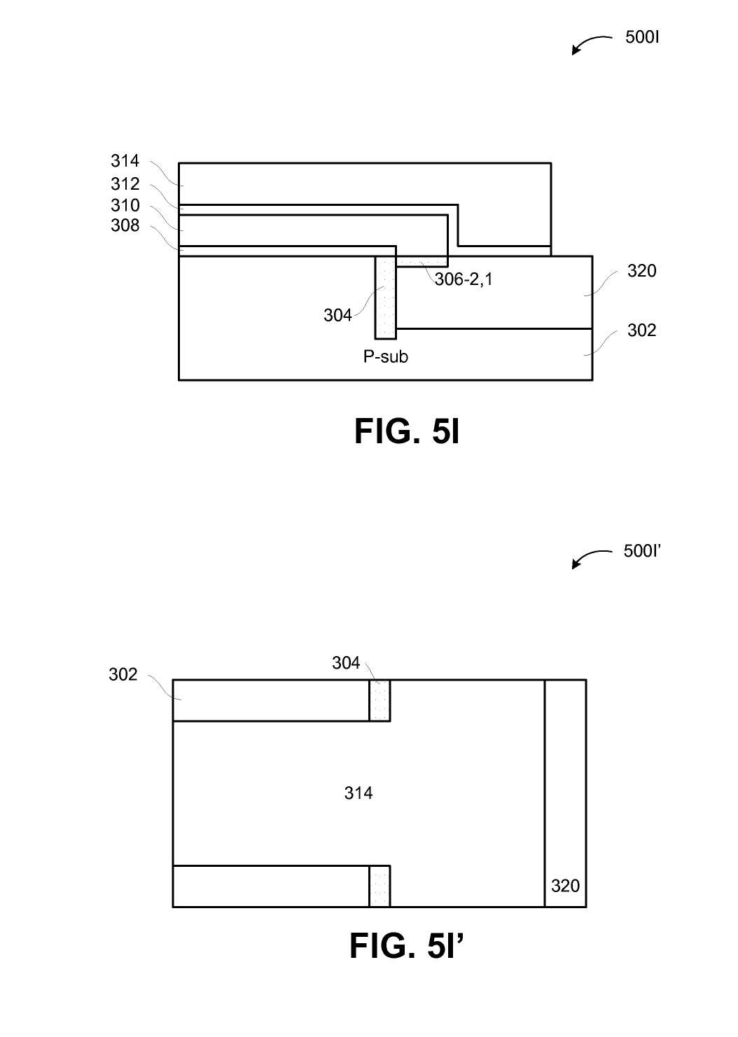

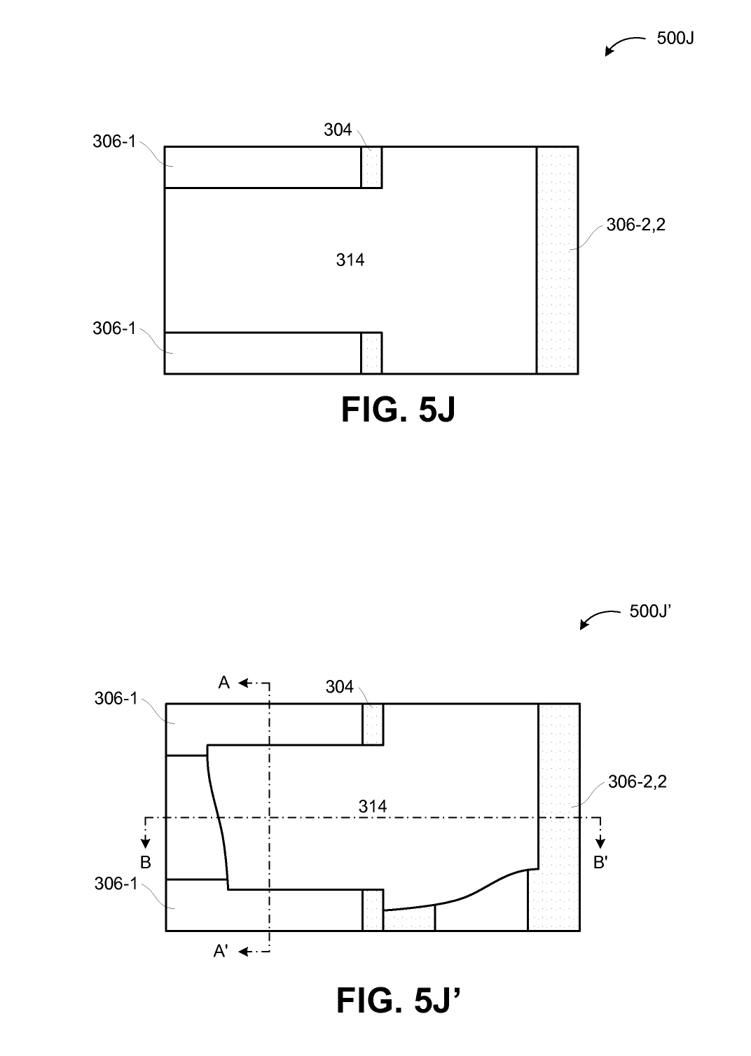

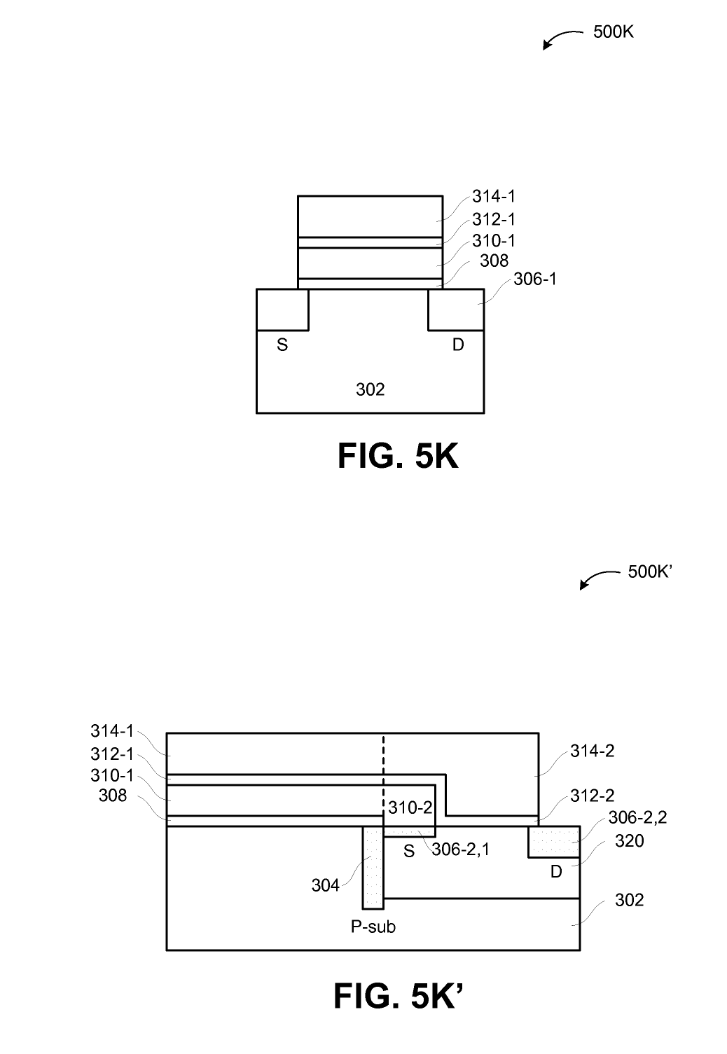

FIG. 5A illustrates a substrate utilized with the process flow to manufacture the connecting storage gate memory device, according to at least some examples disclosed herein.

As shown in FIG. 5A, a diagram 500A may include a substrate 302 may be provided. Details on the substrate 302 may be described with reference to FIG. 1 in connection with substrate 102. In this example, the substrate 302 can be lightly p-type doped by ion implantation.

FIG. 5B illustrates a shallow trench isolation (STI) in the substrate that defines active regions on the substrate formed in the manufacture of the connecting storage gate memory device, according to at least some examples disclosed herein.

Next, as shown in FIG. 5B, a diagram 500B may include an STI 304 may be formed in the substrate 302 to define the active regions in the substrate. For example, a shallow trench isolation (STI) 304 may be formed by first etching trenches in the substrate 302, then filling the trenches with oxides (e.g., silicon oxide) or other dielectrics. In this example, STI 304 may divides the substrate into the different active regions. Here, for convenience, the active region on the left side of the STI referred to as “the first active region”, while the active region on the right side of the STI referred to as “the second active region.” In the second active region, a lightly doped n-type well region 320 may be formed. For example, a mask layer (e.g., photoresist, not shown) shielding the first active region, while the second active area was implanted by n-type dopants such as P, As, etc., or their combinations, to form the n-type well region 320. Thereafter, the mask layer may be removed.

FIG. 5C illustrates a p-type doped region formed in the manufacture of the connecting storage gate memory device, according to at least some examples disclosed herein.

As shown in a diagram 500C of FIG. 5C, in the n-type well region in the second active region, a p-type doped region 306-2,1 may be formed. In this example, the p-type doped region 306-2,1 may act as the source region of the assist transistor, which may be formed as follows. A mask layer 322 may form openings to expose a portion of the second active area on the substrate. The mask layer 322 may be photoresist, for example. In this example, the exposed portion of the second active region may be the area immediately adjacent to the STI 304. As shown by arrows in the FIG., the p-type dopants may be implanted through the opening to the second active region to form a heavily p-type doped region 306-2,1. Examples of the p-type dopants include one or more from a set of: boron (B), Indium (In), difluoroboron (BF₂), and a combination from the set. Then, the mask layer 322 may be removed.

FIG. 5C′ illustrates a top view of the memory device after the formation of the doped region in the manufacture of the connecting storage gate memory device, according to at least some examples disclosed herein. FIG. 5D illustrates a memory gate dielectric layer on a surface of the substrate formed in the manufacture of the connecting storage gate memory device, according to at least some examples disclosed herein. FIG. 5E illustrates the dielectric layer patterned in the manufacture of the connecting storage memory device, according to at least some examples disclosed herein.

As shown in a diagram 500C′ in FIG. 5C′, the doped region 306-2,1 may be extended and may be located adjacent to the STI 304. Subsequently, as shown in a diagram 500D of FIG. 5D, a pre-patterned memory gate dielectric layer is formed by one from a set of: surface thermal oxidation and/or depositing an oxide layer 308′ on a surface of the substrate. The dielectric layer 308′ (i.e. an oxide layer) may become patterned, for example, using reactive ion etching (RIE) to remove the portion located on the second active region, as shown in a diagram 500E of FIG. 5E. The remaining part of the oxide layer 308′ may serve as the partially patterned memory gate dielectric layer 308″ for the main memory transistor. The portion of the partially patterned memory gate dielectric layer 308″ near the edge of the second active region may sit on top of the STI 304.

FIG. 5F illustrates a layer of polysilicon deposited on a partially patterned memory gate dielectric layer in the manufacture of the connecting storage gate memory device, according to at least some examples disclosed herein. FIG. 5G illustrates the partially patterned connecting storage gate layer on the partially patterned memory dielectric layer in the manufacture of the connecting storage gate memory device, according to at least some examples disclosed herein.

As shown in a diagram 500F of FIG. 5F, for example, by film deposition, a layer of polysilicon 310′ may be formed on the partially patterned memory gate dielectric layer 308″. The polysilicon layer 310′ may be patterned. Using RIE, the portion located in the second active region and outside of the doped region 306-2,1 may be removed, as shown in a diagram 500G of FIG. 5G. The partially patterned connecting storage gate layer 310″ may include a portion 310″-1 located on the first active region, and to be defined as the storage gate electrode for the main memory transistor and a portion 310″, which may extend into the second active region located over the STI and the doped region 306-2,1. The edge of the connecting storage gate at the second active region may not be aligned with the edge of the doped region 306-2,1.

The extension portion 310-2 may be doped, for example, by p-type doping. The doped extension portion may serve as the electrical connection between the storage gate electrode 310-1 and the doped region of 306-2,1. It should also be noted here that, unlike the process described in FIG. 5C that utilized pre-doping to form the doped region 306-2,1, the doped region 306-2,1 may be simultaneously formed when doping the extension portion 310-2, such as by implanting both the doped region 306-2,1 and the extension portion 310-2 simultaneously.

FIG. 5I illustrates exposed portions of a second active region in the manufacture of the connecting storage gate memory device, according to at least some examples disclosed herein. FIG. 5I′ illustrates exposed portions of a first active region in the manufacture of the connecting storage gate memory device, according to at least some examples disclosed herein.

Following the structure shown in FIG. 5G, deposition may be utilized to sequentially form an oxide layer 312′ and a polysilicon layer 314′. Then, pattern and reactive ion etching (RIE) may be used on the stacked layers of the partially patterned memory dielectric layer 308″, the partially patterned connecting storage gate layer 310″, an oxide layer 312′, and a polysilicon layer 314′ to form the gate stacks for the main memory transistor and the assist transistor, the control gate dielectric layer 312, and the gate electrode layer 314, as seen in a diagram 500H of FIG. 5H. In the first active region, on opposite sides of the gate stack, along the first direction (the vertical direction in FIG. 5I′), portions of the first active region are exposed. In the second active region, on the right side of the gate stack, along the second direction (the horizontal direction in a diagram 500I′ of FIG. 5I′), portions of the second active region are exposed, as shown in a diagram 500I of FIG. 5I and in the diagram 500I′ of FIG. 5F).

FIG. 5J illustrates heavily n-type doped regions in the first active area and a heavily p-type doped region in the second active region in the manufacture of the connecting storage memory device, according to at least some examples disclosed herein.

Subsequently, as shown in a diagram 500J of FIG. 5J, through use of ion implantation and by using the patterned gate stack as a mask, the heavily n-type doped regions 306-1 may be formed in the first active area and the doped region 306-2,2, which may be heavily p-type doped, may be formed in the second active region. For example, the mask layer (e.g., photoresist, not shown) may shield the second active region, while n-type dopants may be implanted to form the doped regions 306-1. Examples of n-type dopants include, among others, phosphorous (P), arsenic (As), and combinations of those listed. The implantation may also enter the gate electrode layer 314. Thereafter, the shielding layer may be removed. In addition, the mask layer (e.g., photoresist, not shown) may shield the first active region, while the p-type dopants may be implanted into the second active region to form the doped regions 306-2, 2. Examples of p-type dopants include, among others, such as boron (B), indium (In), difluoroboron (BF₂), and the combination of those listed. The implantation may also enter the gate electrode layer 314. Thereafter, the shielding layer may be removed. After the ion implantation, annealing may be performed to activate the implanted ions.

FIG. 5J′ illustrates a top view of the device in FIG. 5J after part of the stack is cut away in the manufacture of the connecting storage gate memory device, according to at least some examples disclosed herein.

FIG. 5J′ is top view of the device in FIG. 5J after part of the stack cut away. As shown in FIG. 5J′, the n-type dopant regions 306-1 may be located on opposite sides of the gate stack along the first direction and may overlap with portion of the gate stack. The n-type doped regions 306-1 may act as the source/drain regions of the main memory transistor. The p-type doped region may be located along the second direction and on the right side of the gate stack and may overlap with at least one portion of the gate stack. The doped region 306-2,2, which may be p-type doped region, and the previously formed p-type doped region, 306-2,1, may act as the source/drain regions of the assist transistor.

FIG. 5K illustrates a cross-sectional view along the AA′ line in FIG. 5J′ in the manufacture of the connecting storage gate memory device, according to at least some examples disclosed herein.

FIG. 5K may illustrate the cross-sectional view along the AA′ line in FIG. 5J′. As shown in a diagram 500K of FIG. 5K, in the first active region, the memory gate dielectric layer 308, the connecting storage gate 310-1, the portion of the gate dielectric layer 312 on the first active region 312-1, and the portion of the gate electrode layer 314 on the first active region 314-1 may form a gate stack of the main memory transistor. The portion of the gate dielectric layer 312 on the first active region 312-1 may act as the control gate dielectric layer of the main memory transistor. The portion of the gate electrode layer 314 on the first active region 314-1 may serve as the gate electrode of the memory transistor. In the first active region, the source/drain regions may be formed on opposite sides of the gate stack (along the first direction).

FIG. 5K′ illustrates a cross-sectional view along the BB′ line in FIG. 5J′ in the manufacture of the connecting storage gate memory device, according to at least some examples disclosed herein.

FIG. 5K′ illustrates the cross-sectional view along the BB′ line in FIG. 5J′. As shown in a diagram 500′ of FIG. 5K′, on the second active region, the portion of gate dielectric layer 312 on the second active region 312-2 and the portion of a gate electrode layer 314 on the second active region 314-2 may form the gate stack for the assist transistor. The portion of gate dielectric layer 312 on the second active region 312-2 may serve as the gate dielectric layer as the assist transistor. The portion of a gate electrode layer 314 on the second active region 314-2 may serve act as the gate electrode of the assist transistor. In the second active region, on opposite sides of the gate stack of the assist transistor, along the second direction, the doped region 306-2,1 and the doped region 306-2,2 may be formed. In addition, the extension portion 310-2 may connect the connecting storage gate 310-1 of the main memory transistor and the source electrode of the assist transistor.

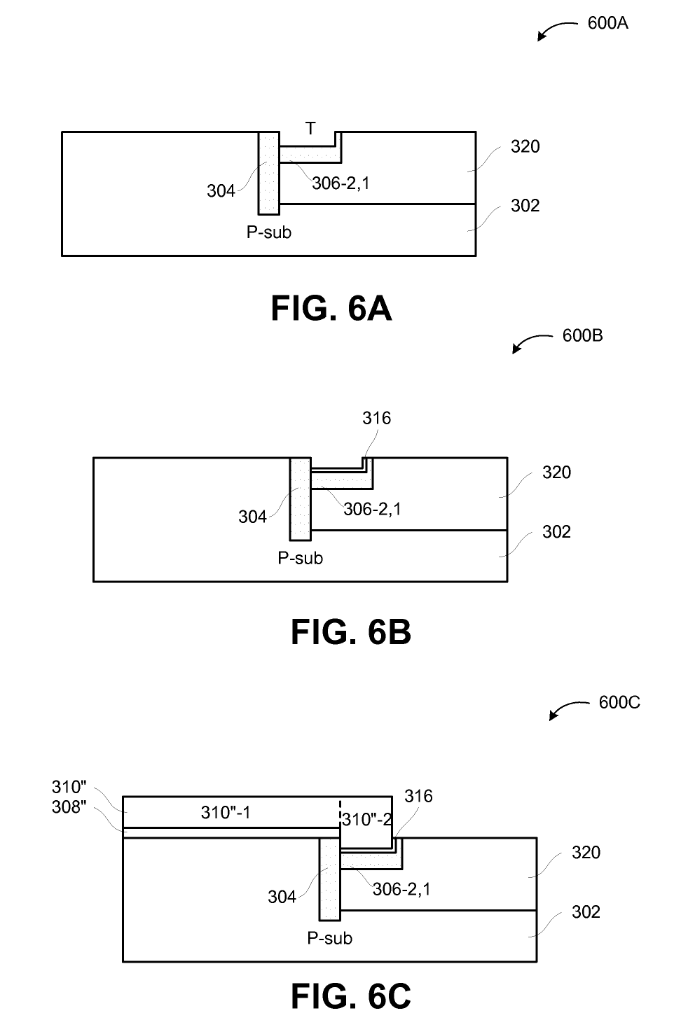

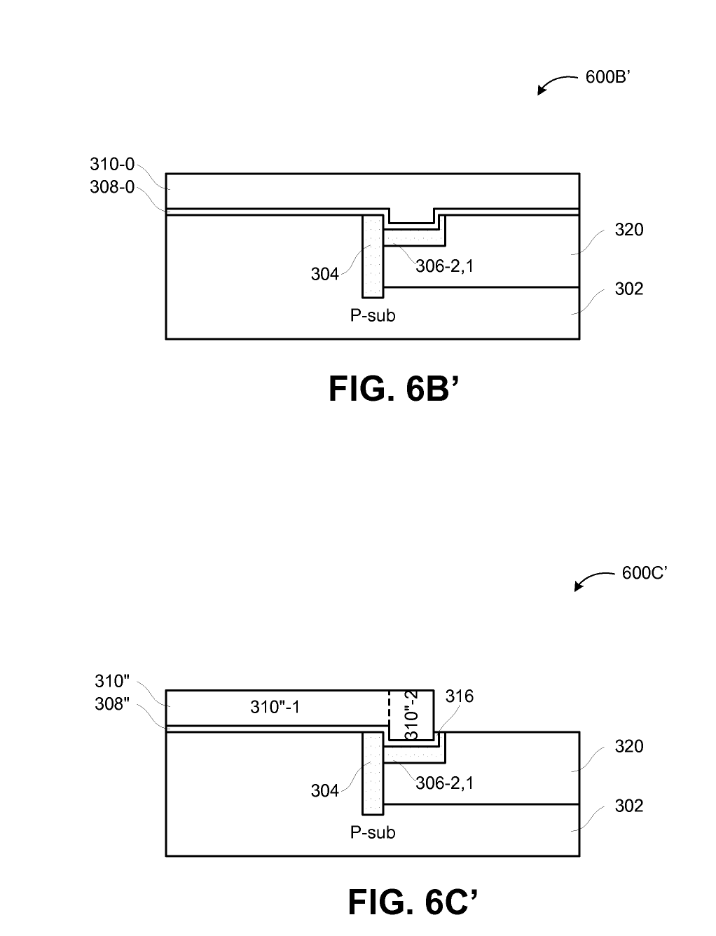

FIG. 6A illustrates a trench near a shallow trench isolation (STI) in a doped region of a connecting storage gate memory device with an additional contacting tunnel oxide, according to at least some embodiments disclosed herein.

After the fabrication process described in FIG. 5A-5C, selective etching may be used to form the trench T near the shallow trench isolation (STI) 304 in the doped region 306-2,1, as shown in a diagram 600A of FIG. 6A. Examples of selective etching include, among other things, reactive ion etching (RIE). The trench T may extend through a length of the doped region 306-2,1, along the first direction.

FIG. 6B illustrates a thin tunnel dielectric layer formed on sidewalls and a bottom of a trench of a connecting storage gate memory device with an additional contacting tunnel dielectric, according to at least some embodiments disclosed herein.

As shown in a diagram 600B of FIG. 6B, by one from a set of: surface thermal oxidation and deposition, a contact tunnel dielectric layer 316 may be formed on the sidewalls and the bottom of the trench T. In this operation, the upper surface of the substrate may also be formed with a thin layer of dielectric.

FIG. 6C illustrates an extension of a connecting storage gate over the additional contacting tunnel oxide, according to at least some embodiments disclosed herein.

As shown in a diagram 600C of FIG. 6C, in conjunction with the process described in FIGS. 5D and 5E, the dielectric layer 308 may be formed. In conjunction with the process described in FIGS. 5F and 5G, the connecting storage gate layer 310 may be formed on the dielectric layer 308. The connecting storage gate layer 310 may be filled in the trench T after the contact tunneling dielectric layer 316 is formed inside the Trench T. Thus, the doped region 306-2,1, may be connected with the extension portion 310-2 and the connecting storage gate 310-1 of the main transistor via the contact tunneling dielectric layer 316.

Similarly, instead of forming the doped region 306-2,1 first, the doping of the region 306-2,1 may be carried out simultaneously with the doping for the extended portion 310-2. Then, following the process described in FIG. 5H-5K′, the example of the connecting storage gate memory device may be realized, whose structure is similar to the memory device obtained in FIG. 5K-5K′, except for the inserted contact tunneling dielectric layer 316.

FIG. 6B′ illustrates a dielectric layer of a connecting storage gate memory device with an additional contacting tunnel oxide, according to at least some examples disclosed herein.

According to another example of the present disclosure, the contacting tunneling dielectric layer 316 may be formed in different ways. As illustrated in a diagram 600B′ of FIG. 6B′, after forming the trench T, for example, by one from a set of: deposition and surface thermal oxidation on the surface of substrate, a dielectric layer 308″ may be formed. A storage gate layer 310″, such as a polycrystalline silicon gate electrode layer, may be deposited on the dielectric layer 308″.

FIG. 6C′ illustrates an extension of a connecting storage gate layer of a connecting storage gate memory device over an additional contacting tunnel oxide, according to at least some examples disclosed herein.

Next, as shown in a diagram 600C′ of FIG. 6C′, through utilizing pattern and reactive ion etching (RIE) on the dielectric layer 308″ and the storage gate layer 310″, the connecting storage gate layer 310 may be obtained. The remaining portion of the dielectric layer 308″ may be located substantially beneath the connecting storage gate layer 310. The portion of 308″ on the first active area may serve as the memory gate dielectric layer 308 for the main memory transistor, and the portion on the second active region (specifically, in the trench) may function as the contact tunneling dielectric layer 316.

In some examples, instead of forming the doped region 306-2,1 first, the doping of the doped region 306-2,1 may be carried out simultaneously with the doping for the extension portion 310-2. Then, following the process described in FIG. 5H-5K′, the example of the connecting storage gate memory device may be realized.

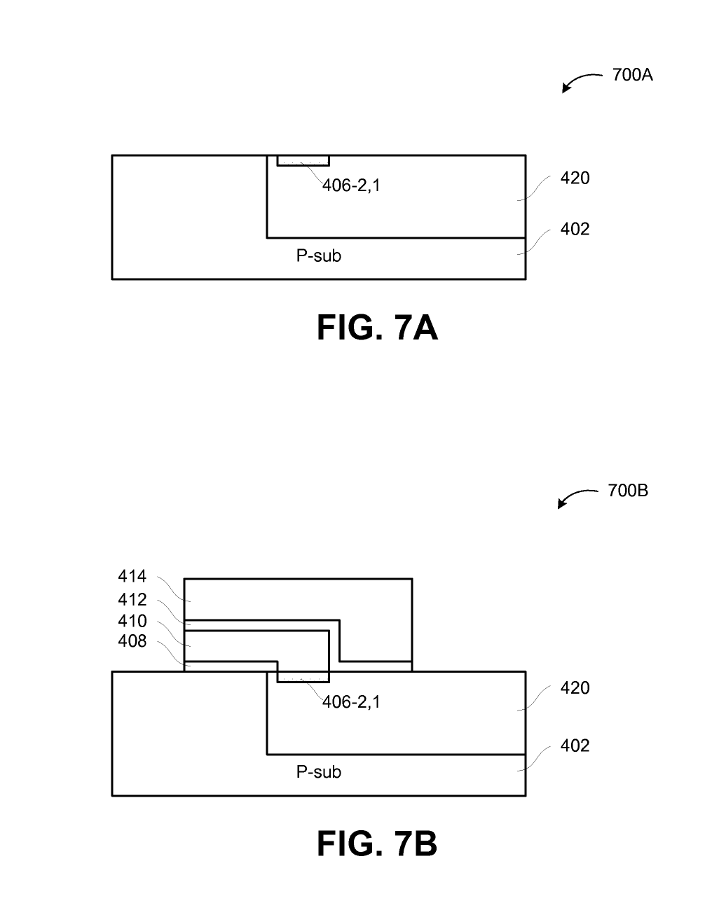

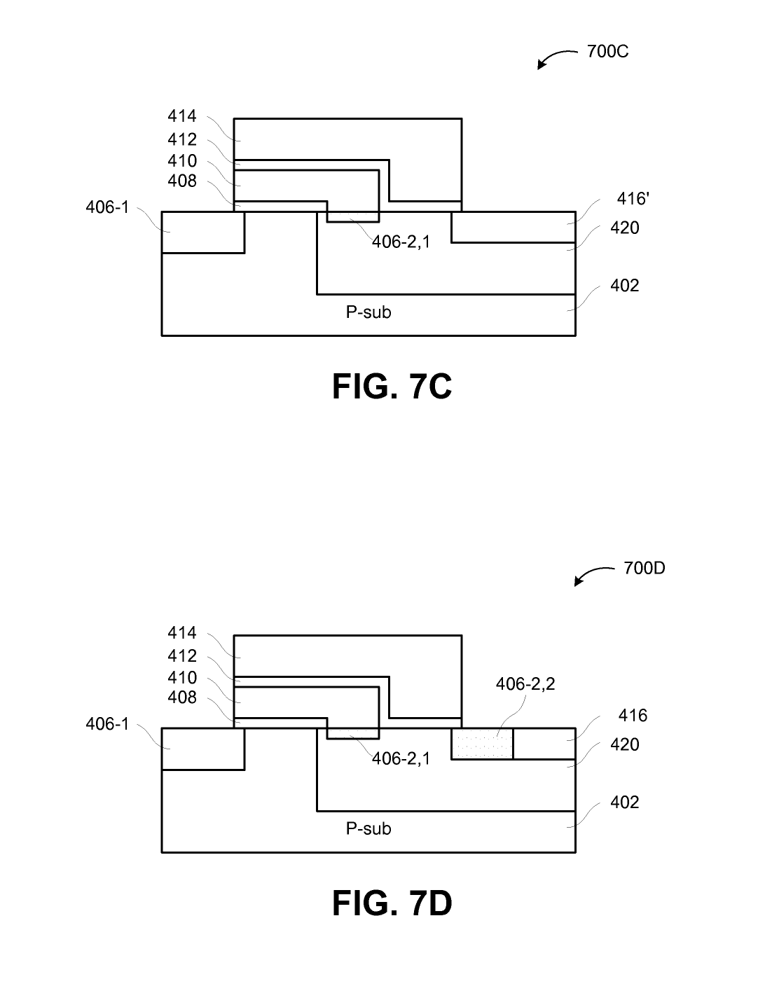

FIG. 7A illustrates a substrate utilized for a partial fabrication process of the connecting storage gate memory device with a main memory transistor and an assist transistor in an active region, according to at least some examples disclosed herein.

As shown in a diagram 700A of FIG. 7A, a substrate 402 may be provided. Details on the substrate 402 may be described with the reference to the description of substrate 102 in FIG. 1. In this example, the substrate 402 may be lightly p-type doped by ion implantation. An STI (not shown) may form to define active regions in the substrate. The FIG. 7A shows the active area.

The lightly n-type well region 320 and the heavily p-type doped region 406,2-1 may be formed in the substrate 402 by ion implantation. The patterned masking layers may be used as masks for ion implantation to form doped regions with shapes.

FIG. 7B illustrates a gate stack formed for use in a partial fabrication process of the connecting storage gate memory device with a main memory transistor and an assist transistor in an active region, according to at least some examples disclosed herein. FIG. 7C illustrates parts of source/region regions formed for use in a partial fabrication process of the connecting storage gate memory device with a main memory transistor and an assist transistor in an active region, according to at least some examples disclosed herein. FIG. 7D illustrates a p-type doped region formed in the n-type doped region for use in a partial fabrication process of the connecting storage gate memory device with a main memory transistor and an assist transistor in an active region, according to some examples disclosed herein.

As shown in a diagram 700B of FIG. 7B, through film depositing and patterning, the gate stack may be formed. The gate stack may include the memory gate dielectric layer 408, the connecting storage gate layer 410, a control gate dielectric layer 412, and the gate electrode layer 414. The stack may be formed by using a similar process as described in FIG. 5D-5H. As shown in a diagram 700C of FIG. 7C, the gate stack may be used as a mask. A heavily n-doped region 406-1 and the n-type doped region 416′ may be formed in the substrate by ion implantation. Then, as shown in FIG. 7D, by ion implantation, a p-type doped region 406-2,2 may be formed in the n-type doped region 416′. The connecting storage gate memory device described in this example may be realized and the memory device is substantially the same as the memory devices described in FIG. 4.

In the above examples, examples described include the structure of bulk silicon planar transistors, but the present disclosure is not limited thereto. The present disclosure is also applicable to other device structures, for example, such as FinFET, vertical transistors, SOI devices. The semiconductor material used may include one or more from a set of: silicon, germanium, III-V family, and II-V group, among others. The semiconductor material may be one or more from a set of: epitaxially grown materials and silicon on insulator (SOI) materials.

In the above description, the examples used n-type doping and p-type doping. It should be understood that those skilled in the art, there can be different doping, for example, in the above examples, the n-type and p-type doping can be interchanged.

The memory device described in FIGS. 1-7D may increase the write and erase speed from a millisecond level to a nanosecond level, which may help the memory device to serve as one or more from a set of: a low-energy consumption static random access memory (SRAM), and a dynamic random access memory (DRAM), among others. The memory device may be utilized in embedded memory applications. The memory device may increase the charge storage capacity. The disclosure may improve the speed of operation of the storage unit, may reduce power consumption, and may increase the charge storing capacity.

In the above description, the composition of the layers and the etching of the details of the detailed description are not made. However, the skilled person will appreciate that, through various techniques, formation of the desired shape of a layer, region, and the like, is possible. Further, to form the same structure, those skilled in the art may devise a method as described above is not exactly the same way. Further, although in the above examples are separately described, but this does not mean that the implementation of the various examples of the measures may not be combined to advantage. While the various features described above, respectively, in various examples, but this does not mean that these features cannot be advantageously used in combination.

The present disclosure is not to be limited in terms of the particular examples described in this application, which are intended as illustrations of various aspects. Many modifications and variations can be made without departing from its spirit and scope Functionally equivalent methods and apparatuses within the scope of the disclosure, in addition to those enumerated herein, will be possible from the foregoing descriptions. Such modifications and variations are intended to fall within the scope of the appended claims. The present disclosure is to be limited only by the terms of the appended claims, along with the full scope of equivalents to which such claims are entitled. It is to be understood that this disclosure is not limited to particular methods, systems, or components, which can, of course, vary. It is also to be understood that the terminology used herein is for the purpose of describing particular examples only, and is not intended to be limiting.

In addition, the mechanisms of the subject matter described herein are capable of being distributed as a program product in a variety of forms, and that an illustrative example of the subject matter described herein applies regardless of the particular type of signal bearing medium used to actually carry out the distribution. Examples of a signal bearing medium include, but are not limited to, the following: a recordable type medium such as a floppy disk, a hard disk drive, a Compact Disc (CD), a Digital Versatile Disk (DVD), a digital tape, a computer memory, etc.; and a transmission type medium such as a digital and/or an analog communication medium (for example, a fiber optic cable, a waveguide, a wired communications link, a wireless communication link, etc.).

Those skilled in the art will recognize that it is common within the art to describe devices and/or processes in the fashion set forth herein, and thereafter use engineering practices to integrate such described devices and/or processes into data processing systems. That is, at least a portion of the devices and/or processes described herein may be integrated into a data processing system via a reasonable amount of experimentation. Those having skill in the art will recognize that a typical data processing system generally includes one or more of a system unit housing, a video display device, a memory such as volatile and non-volatile memory, processors such as microprocessors and digital signal processors, computational entities such as operating systems, drivers, graphical user interfaces, and applications programs, one or more interaction devices, such as a touch pad or screen, and/or control systems including feedback loops.

A typical data processing system may be implemented utilizing any suitable commercially available components, such as those typically found in data computing/communication and/or network computing/communication systems. The herein described subject matter sometimes illustrates different components contained within, or connected with, different other components. It is to be understood that such depicted architectures are merely exemplary, and that in fact many other architectures may be implemented which achieve the same functionality. In a conceptual sense, any arrangement of components to achieve the same functionality is effectively “associated” such that particular functionality is achieved. Hence, any two components herein combined to achieve a particular functionality may be seen as “associated with” each other such that the particular functionality is achieved, irrespective of architectures or intermediate components. Likewise, any two components so associated may also be viewed as being “operably connected”, or “operably coupled”, to each other to achieve the particular functionality, and any two components capable of being so associated may also be viewed as being “operably couplable”, to each other to achieve the particular functionality. Specific examples of operably couplable include but are not limited to physically connectable and/or physically interacting components and/or wirelessly interactable and/or wirelessly interacting components and/or logically interacting and/or logically interactable components.

With respect to the use of substantially any plural and/or singular terms herein, those having skill in the art can translate from the plural to the singular and/or from the singular to the plural as is appropriate to the context and/or application. The various singular/plural permutations may be expressly set forth herein for sake of clarity.

It will be understood by those within the art that, in general, terms used herein, and especially in the appended claims (for example, bodies of the appended claims) are generally intended as “open” terms (for example, the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present. For example, as an aid to understanding, the following appended claims may contain usage of the introductory phrases “at least one” and “one or more” to introduce claim recitations. However, the use of such phrases should not be construed to imply that the introduction of a claim recitation by the indefinite articles “a” or “an” limits any particular claim containing such introduced claim recitation to examples containing only one such recitation, even when the same claim includes the introductory phrases “one or more” or “at least one” and indefinite articles such as “a” or “an” (for example, “a” and/or “an” should be interpreted to mean “at least one” or “one or more”); the same holds true for the use of definite articles used to introduce claim recitations. In addition, even if a specific number of an introduced claim recitation is explicitly recited, those skilled in the art will recognize that such recitation should be interpreted to mean at least the recited number (for example, the bare recitation of “two recitations,” without other modifiers, means at least two recitations, or two or more recitations).

Furthermore, in those instances where a convention analogous to “at least one of A, B, and C, etc.” is used, in general such a construction is intended in the sense one having skill in the art would understand the convention (for example, “a system having at least one of A, B, and C” would include but not be limited to systems that have A alone, B alone, C alone, A and B together, A and C together, B and C together, and/or A, B, and C together, etc.). It will be further understood by those within the art that virtually any disjunctive word and/or phrase presenting two or more alternative terms, whether in the description, claims, or drawings, should be understood to contemplate the possibilities of including one of the terms, either of the terms, or both terms. For example, the phrase “A or B” will be understood to include the possibilities of “A” or “B” or “A and B.”

As will be understood by one skilled in the art, for any and all purposes, such as in terms of providing a written description, all ranges disclosed herein also encompass any and all possible subranges and combinations of subranges thereof. Any listed range can be easily recognized as sufficiently describing and enabling the same range being broken down into at least equal halves, thirds, quarters, fifths, tenths, etc. As a non-limiting example, each range discussed herein can be readily broken down into a lower third, middle third and upper third, etc. As will also be understood by one skilled in the art all language such as “up to,” “at least,” “greater than,” “less than,” and the like include the number recited and refer to ranges which can be subsequently broken down into subranges as discussed above. Finally, as will be understood by one skilled in the art, a range includes each individual member. Thus, for example, a group having 1-3 cells refers to groups having 1, 2, or 3 cells. Similarly, a group having 1-5 cells refers to groups having 1, 2, 3, 4, or 5 cells, and so forth.

While various aspects and examples have been disclosed herein, other aspects and examples will be apparent to those skilled in the art. The various aspects and examples disclosed herein are for purposes of illustration and are not intended to be limiting, with the true scope and spirit being indicated by the following claims.

1. A memory device comprising:
a substrate;
a memory transistor comprising:
a gate stack comprising:
a memory gate dielectric layer positioned over the substrate;
a connecting storage gate layer positioned over the memory gate dielectric layer;
a control gate dielectric layer positioned over the connecting storage gate layer;
a gate electrode layer positioned over the control gate dielectric layer; and
an assist transistor comprising:
a gate stack formed on the substrate; and
source/drain regions located on opposite sides of gate stack, wherein one of the source/drain regions is connected to the connecting storage gate of the memory transistor.

2. The memory device of claim 1, wherein the assist transistor is configured to one from a set of: store charges from the connecting storage gate layer of the memory transistor and remove charges from the connecting storage gate layer of the memory transistor.

3. The memory device of claim 1, wherein the gate stack further comprises:
a gate dielectric layer positioned over the substrate;
a gate electrode positioned over the gate dielectric layer; and
the gate electrode connected to the control gate electrode of the memory transistor;

4. The memory device of claim 1, wherein the connecting storage gate of the memory transistor extends and makes contact with one of the source/drain regions of the assist transistor.

5. The memory device of claim 3, wherein the control gate electrode of the memory transistor is connected to and integrates continuously with the gate electrode of the assist transistor.

6. The memory device of claim 1, wherein the control gate dielectric of the memory transistor and the gate dielectric of the assist transistor are integrated together continuously.

7. The memory device of claim 1, wherein the memory device further comprises:
a first active region in the substrate, wherein the memory transistor is formed in the first active region;
a second active region in the substrate, wherein the assist transistor is formed in the second active region; and
a shallow trench isolation (STI) that separates the first active region and the second active region.

8. The memory device of claim 7, wherein the memory device further comprises one or more from a set of:
the channel of the memory transistor extends along a first direction in the first active region; and
the channel of the assist transistor extends along a second direction in the second active region, wherein the first direction crosses the second direction.

9. The memory device of claim 1, wherein the memory device further comprises:
a contact tunnel dielectric layer located in one from a set of: the source/drain region of the assist transistor; and
the connecting storage gate of the memory transistor connects to one from a set of: the source/drain region of the assist transistor via the contact tunnel dielectric layer.

10. The memory device of claim 1, wherein the memory transistor and the assist transistor are formed in the same active region of the substrate.

11. The memory device of claim 10, wherein the memory device further comprises:
a well region of the second doping type formed in the active region, wherein the active region is a first doping type;
an assist transistor comprising:
a source region and a drain region of the first doping type formed in the well region; and
a memory transistor comprising:
a first source/drain region of the second doping type formed outside the well region, wherein a second source/drain region formed by the well region of the second doping type.

12. The memory device of claim 11, wherein the memory device further comprises:
a second doping type contact region formed in the well region.

13. The memory device of claim 1, wherein the memory transistor is a first conducting type device, the assist transistor is a second conducting type device, and the first conducting type and the second conducting type are of opposite polarity.

14. The memory device of claim 1, wherein the assist transistor is a metal-oxide-semiconductor (MOS) type transistor.

15. A method to operate a memory device, the method comprising:
in a memory device that comprises:
a substrate;
a memory transistor comprising:
a gate stack comprising:
a memory gate dielectric layer positioned over the substrate;
a connecting storage gate layer positioned over the memory gate dielectric layer;
a control gate dielectric layer positioned over the connecting storage gate layer;
a gate electrode layer positioned over the control gate dielectric layer; and
an assist transistor comprising:
a gate stack formed on the substrate; and
source/drain regions located on opposite sides of gate stack,
wherein one of the source/drain regions is connected to the connecting storage gate of the memory transistor;
in response to a determination that the assist transistor is turned on, one from a set of:
storing charges from the connecting storage gate of the memory transistor by the assist transistor at on stage, and
removing charges from the connecting storage gate of the memory transistor by the assist transistor at on stage; and
in response to a determination that the memory transistor is turned on and the assist transistor is turned off, reading stored data from the memory transistor.

16. A method to manufacture a memory device, the method comprising:
forming a memory transistor on a substrate, the method comprising:
forming a gate stack, the method comprising:
forming a memory gate dielectric layer positioned over the substrate;
forming a connecting storage gate layer positioned over the memory gate dielectric layer;
forming a control gate dielectric layer positioned over the connecting storage gate layer;
forming a gate electrode layer positioned over the control gate dielectric layer; and
forming an assist transistor comprising:
forming a gate stack formed on the substrate;
forming source/drain regions located on opposite sides of the gate stack; and
connecting the connecting storage gate layer of the memory transistor to one of the source/drain regions of the assist transistor.

17. The method of claim 16, further comprising:
defining a first active region and a second active region in a substrate;
separating the first active region and the second active region by shallow trench isolation (STI);
forming the memory transistor and the assist transistor comprising:
forming a first source/drain region of the assist transistor in the second active region;
forming the gate stack of the memory transistor in the first active region;
forming the gate stack of the assist transistor in the second active region;
using the gate stack as a mask to form the source/drain regions of the memory transistor in the first active region;
forming a second source/drain region of the assist transistor in the second active region; and
connecting the connecting storage gate of the memory transistor to the first source/drain region of the assist transistor comprising:
extending the connecting storage gate of the memory transistor and therefore, contacting the first source/drain region of the assist transistor.

18. The method of claim 16, further comprising:
forming a contact tunneling dielectric layer in a substrate; and
one of source/drain regions of the assist transistor via the contact tunneling dielectric layer connecting to the connecting storage gate of the memory transistor.

19. The method of claim 16, further comprising:
forming a memory transistor and an assist transistor comprising:
forming a well region of a second doping type in an active region of a first doping type in a substrate;
forming a first source/drain region of a first doping type of the assist transistor in the well region;
forming the gate stack of the memory transistor and the gate stack of the assist transistor in the active region; and
using the gate stack as a mask to:
form a source/drain region of the second doping type of the memory transistor, and
form a second source/drain region of the first doping type of the assist transistor in the well region.
extending the connecting storage gate of the memory transistor to contact the first source/drain regions of the assist transistor.

20. The method of claim 16, further comprising:
the control gate electrode of the memory transistor and the gate electrode of the assist gate transistor integrated continuously; and
the control gate dielectric of the memory transistor and the gate dielectric of the assist transistor integrated continuously.
